(19) United States
(12) Patent Application Publication
(10) Pub. No.: US 2014/0335695 A1
(43) Pub. Date: Nov. 13, 2014

(54) EXTERNAL UV LIGHT SOURCES TO MINIMIZE ASYMMETRIC RESIST PATTERN TRIMMING RATE FOR THREE DIMENSIONAL SEMICONDUCTOR CHIP MANUFACTURE

(71) Applicant: Applied Materials, Inc., Santa Clara, CA (US)

(72) Inventors: Olivier LUERE, Sunnyvale, CA (US); Olivier JOUBERT, Meylan (FR)

(21) Appl. No.: 13/892,039

(22) Filed: May 10, 2013

(51) Int. Cl. H01L 21/3065; H01L 21/67

(52) U.S. Cl. CPC H01L 21/3065; H01L 21/67069
USPC 438/709; 156/345.34

(57) ABSTRACT

Embodiments of the present invention provide an apparatus and methods for forming stair-like structures in manufacturing three dimensional (3D) stacking of semiconductor chips. In one embodiment, a method of forming stair-like structures on a substrate includes performing a trimming process on a substrate to trim a patterned photoresist layer disposed on a film stack from a first width to a second width in a processing chamber, wherein the patterned photoresist layer exposes a portion of the film stack uncovered by the patterned photoresist layer during the trimming process, wherein the trimming process further comprises supplying a trimming gas mixture including at least an oxygen containing gas, and providing a light energy in the trimming gas mixture to an edge of the substrate during the trimming process.

### BACKGROUND

1. Field

Embodiments of the present invention generally relate to methods of manufacturing a vertical type semiconductor device, and more particularly to methods of manufacturing a vertical type semiconductor device with stair-like structures.

2. Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate is important to VLSI and ULSI success and to the continued effort to increase circuit density and quality of individual substrates and die.

A patterned mask, such as a photoresist layer, is commonly used in forming structures, such as gate structure, shallow trench isolation (STI), bite lines and the like, on a substrate by etching process. The patterned mask is conventionally fabricated by using a lithographic process to optically transfer a pattern having the desired critical dimensions to a layer of photoresist. The photoresist layer is then developed to remove undesired portion of the photoresist, thereby creating openings in the remaining photoresist.

In order to enable fabrication of next generation devices and structures, three dimensional (3D) stacking of semiconductor chips is often utilized to improve performance of the transistors. By arranging transistors in three dimensions instead of conventional two dimensions, multiple transistors may be placed in the integrated circuits (ICs) very close to each other. Three dimensional (3D) stacking of semiconductor chips reduces wire lengths and keeps wiring delay low. In manufacturing three dimensional (3D) stacking of semiconductor chips, stair-like structures are often utilized to allow multiple interconnection structures to be disposed thereon, forming high-density of vertical transistor devices.

When forming stair-like structures in a film stack disposed on a substrate, an etching process along with a photoresist trimming process are repeatedly performed to etch the film stack with sequentially trimmed photoresist layer as etching masks. In an exemplary embodiment depicted in FIG. 1, a trimmed photoresist layer 108 may serve as an etching mask layer to transfer structures onto a film stack 100 disposed on a substrate 104 to form stair-like structures 110 on the substrate 104. The film stack 100 typically includes alternating layers of conducting layers 102 (shown as 102a, 102b, 102c, 102d) and insulating layers 106 (shown as 106a, 106b, 106c, 106d). The photoresist layer 108 is sequentially trimmed to different dimensions while serving as an etch mask to form stair-like structures 110 having different widths 112.

However, during manufacturing of the stair-like structures 110 on the substrate 104, the widths 111, 112 formed on the two sides of the stair-like structures 110 are often non-uniform and asymmetric. The non-uniform and asymmetric widths 111, 112 formed in the stair-like structures 110 often result from insufficient and unbalanced UV light reaching to different locations of the substrate. Plasma generated during the process is believed to contain UV lights, e.g., photons, and reactive species. It is believed that unbalance amount of the UV light and insufficient reactive species at edges of the substrate often result in different etching rates or trimming rates across the substrate surface. Different etching rate or trimming rate at different locations across the substrate surface may result in asymmetry of the widths 111, 112 formed in the stair-like structures 110 across the substrate surface. Additionally, asymmetric etching rate or trimming rate may also result in defects, such as deformation, line edge roughness or tapered top portion of the features translated into the stair-like structures 110.

Thus, there is a need for improved methods and apparatus that provide symmetric etching rates and/or trimming rates for forming stair-like structures for three dimensional (3D) stacking of semiconductor chips.

### SUMMARY

Embodiments of the present invention provide an apparatus and methods for forming stair-like structures in manufacturing three dimensional (3D) stacking of semiconductor chips. In one embodiment, a method of forming stair-like structures on a substrate includes performing a trimming process on a substrate to trim a patterned photoresist layer disposed on a film stack from a first width to a second width in a processing chamber, wherein the patterned photoresist layer exposes a portion of the film stack uncovered by the patterned photoresist layer during the trimming process, wherein the trimming process further comprises supplying a trimming gas mixture including at least an oxygen containing gas, and providing a light energy in the trimming gas mixture to an edge of the substrate during the trimming process.

In another embodiment, an apparatus for manufacturing stair-like structures in a film stack for three dimensional stacking of semiconductor chips includes a chamber body having a chamber sidewall and a chamber lid disposed on the chamber sidewall defining an interior volume of an etching processing chamber, a substrate support pedestal disposed in the interior volume of the etching processing chamber, a showerhead assembly disposed opposite to the substrate support pedestal, and a plurality of light source disposed in a periphery region of the chamber lid facing an edge of the substrate support assembly

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic cross-sectional view of conventional stair-like structures formed on a substrate;

FIG. 2 depicts an apparatus utilized to form stair-like structures formed on a substrate in accordance with one embodiment of the present invention;

FIG. 3 depicts a flow diagram of a method for stair-like structures formed on a substrate in accordance with one embodiment of the present invention; and

FIG. 4A-4E depict one embodiment of a sequence for manufacturing stair-like structures formed on a substrate in accordance with the embodiment depicted in FIG. 3; and

FIG. 5 depicts a partial enlarged view of the apparatus depicted in FIG. 2 in accordance with another embodiment of the present invention.

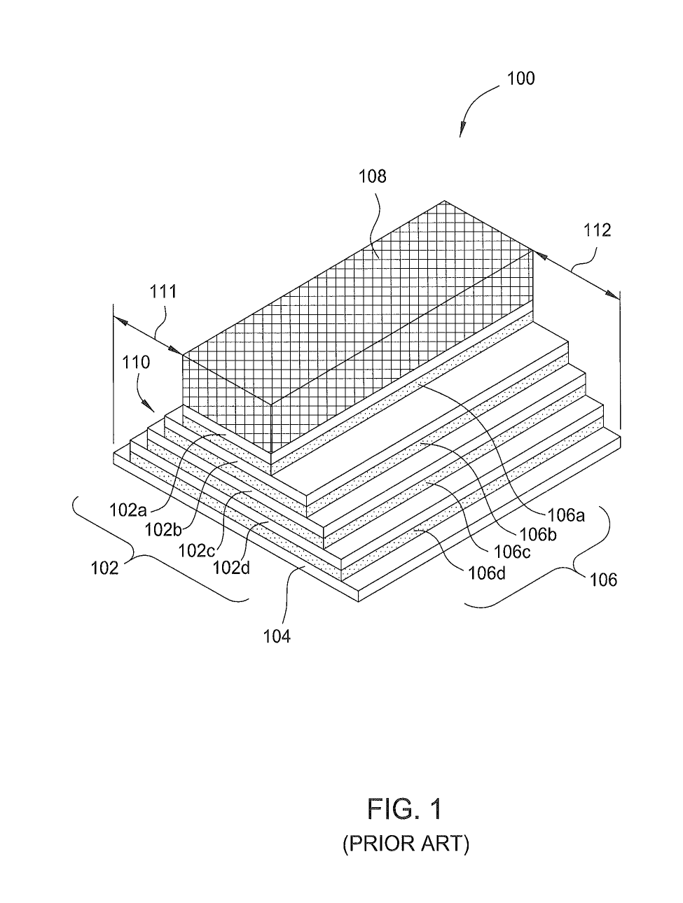

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides an apparatus and methods for forming stair-like structures on a substrate for three dimensional (3D) stacking of semiconductor chips. In one embodiment, the apparatus described herein may have extra light devices disposed in a periphery region of the processing chamber so as to enhance reactive species generation/distributions at the periphery region of the processing chamber. Furthermore, the apparatus may also provide a short distance between a showerhead and a substrate support, where the substrate is disposed on, so as to improve density of the reactive species reaching to the substrate surface. A large gap formed between the substrate support and a chamber wall may also be utilized to have the reactive species to be more symmetric close to the edge of the substrate. In another embodiment, some process parameters, such as a relatively high process pressure, greater than 25 mTorr, regulated RF pulsed power and low oxygen containing flow rate, may also be utilized to improve uniform distribution of the reactive species around the substrate surface, thereby enhancing etch symmetry and trim rate across the substrate surface.

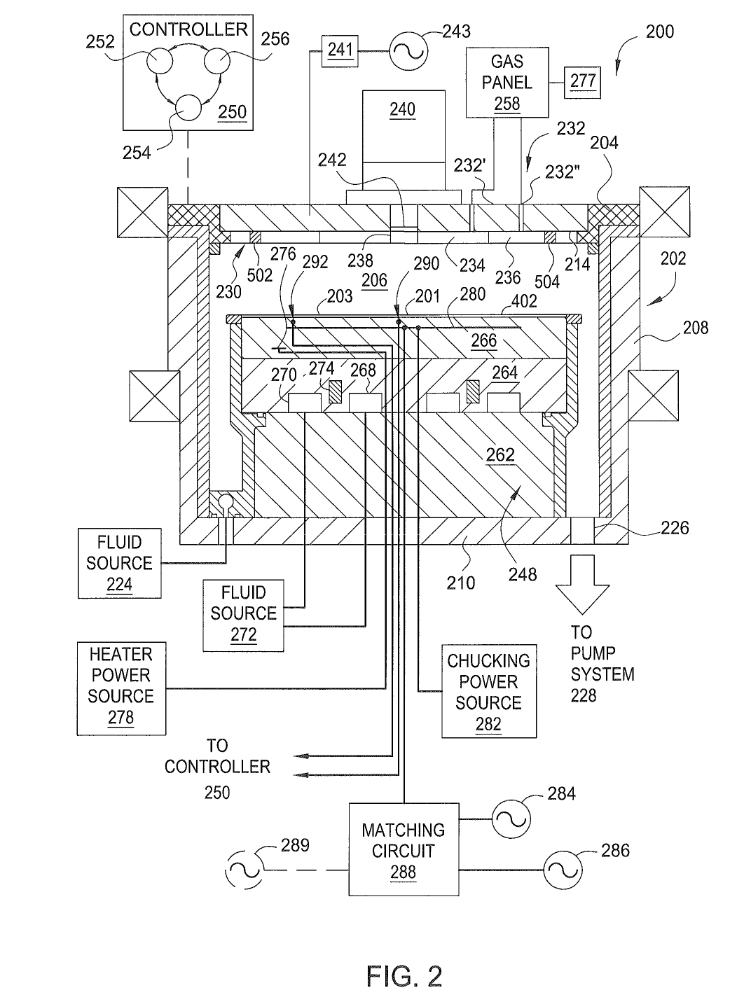

FIG. 2 is a sectional view of one embodiment of a processing chamber 200 suitable for performing an etching and a trimming process to form stair-like structures in a film stack disposed on a substrate with desired uniformity across the substrate. Suitable processing chambers that may be adapted for use with the teachings disclosed herein include, for example, a modified ENABLER® processing chamber available from Applied Materials, Inc. of Santa Clara, Calif. Although the processing chamber 200 is shown including a plurality of features that enable superior etching and trimming performance, it is contemplated that other processing chambers may be adapted to benefit from one or more of the inventive features disclosed herein.

The processing chamber 200 includes a chamber body 202 and a lid 204 which enclose an interior volume 206. The chamber body 202 is typically fabricated from aluminum, stainless steel or other suitable material. The chamber body 202 generally includes sidewalls 208 and a bottom 210. A substrate support pedestal access port (not shown) is generally defined in a sidewall 208 and a selectively sealed by a slit valve to facilitate entry and egress of a substrate 402 from the processing chamber 200. An exhaust port 226 is defined in the chamber body 202 and couples the interior volume 206 to a pump system 228. The pump system 228 generally includes one or more pumps and throttle valves utilized to evacuate and regulate the pressure of the interior volume 206 of the processing chamber 200. In one embodiment, the pump system 228 maintains the pressure inside the interior volume 206 at operating pressures typically between about 10 mTorr to about 500 Torr.

The lid 204 is sealingly supported on the sidewall 208 of the chamber body 202. The lid 204 may be opened to allow excess to the interior volume 206 of the processing chamber 200. The lid 204 includes a window 242 that facilitates optical process monitoring. In one embodiment, the window 242 is comprised of quartz or other suitable material that is transmissive to a signal utilized by an optical monitoring system 240 mounted outside the processing chamber 200.

The optical monitoring system 240 is positioned to view at least one of the interior volume 206 of the chamber body 202 and/or the substrate 402 positioned on a substrate support pedestal assembly 248 through the window 242. In one embodiment, the optical monitoring system 240 is coupled to the lid 204 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed. One optical monitoring system that may be adapted to benefit from the invention is the EyeD® full-spectrum, interferometric metrology module, available from Applied Materials, Inc., of Santa Clara, Calif.

A gas panel 258 is coupled to the processing chamber 200 to provide process and/or cleaning gases to the interior volume 206. In the embodiment depicted in FIG. 2, inlet ports 232′, 232″ are provided in the lid 204 to allow gases to be delivered from the gas panel 258 to the interior volume 106 of the processing chamber 200. In one embodiment, the gas panel 258 is adapted to provide fluorinated process gas through the inlet ports 232′, 232″ and into the interior volume 206 of the processing chamber 200. In one embodiment, the process gas provided from the gas panel 258 includes at least a fluorinated gas, chlorine, and a carbon containing gas, an oxygen gas, a nitrogen containing gas and a chlorine containing gas. Examples of fluorinated and carbon containing gases include CHF₃ and CF₄. Other fluorinated gases may include one or more of C₂F, C₄F₆, C₃F₈ and C₅F₈. Examples of the oxygen containing gas include O₂, CO₂, CO, N₂O, NO₂, O₃, H₂O, and the like. Examples of the nitrogen containing gas include N₂, NH₃, N₂O, NO₂ and the like. Examples of the chlorine containing gas include HCl, Cl₂, CCl₄, CHCl₃, CH₂Cl₂, CH₃CI, and the like. Suitable examples of the carbon containing gas include methane (CH₄), ethane (C₂H₆), ethylene (C₂H₄), and the like.

A showerhead assembly 230 is coupled to an interior surface 214 of the lid 204. The showerhead assembly 230 includes a plurality of apertures that allow the gases flowing through the showerhead assembly 230 from the inlet ports 232′, 232″ into the interior volume 206 of the processing chamber 200 in a predefined distribution across the surface of the substrate 402 being processed in the processing chamber 200.

A remote plasma source 277 may be optionally coupled to the gas panel 258 to facilitate dissociating gas mixture from a remote plasma prior to entering into the interior volume 206 for processing. A RF source power 243 is coupled through a matching network 241 to the showerhead assembly 230. The RF source power 243 typically is capable of producing up to about 3000 W at a tunable frequency in a range from about 50 kHz to about 13.56 MHz.

The showerhead assembly 230 additionally includes a region transmissive to an optical metrology signal. The optically transmissive region or passage 238 is suitable for allowing the optical monitoring system 240 to view the interior volume 206 and/or the substrate 402 positioned on the substrate support pedestal assembly 248. The passage 238 may be a material, an aperture or plurality of apertures formed or disposed in the showerhead assembly 230 that is substantially transmissive to the wavelengths of energy generated by, and reflected back to, the optical monitoring system 240. In one embodiment, the passage 238 includes a window 242 to prevent gas leakage through that the passage 238. The window 242 may be a sapphire plate, quartz plate or other suitable material. The window 242 may alternatively be disposed in the lid 104.

In one embodiment, the showerhead assembly 230 is configured with a plurality of zones that allow for separate control of gas flowing into the interior volume 206 of the processing chamber 200. In the embodiment FIG. 2, the showerhead assembly 230 as an inner zone 234 and an outer zone 236 that are separately coupled to the gas panel 258 through separate inlet ports 232′, 232″.

The substrate support pedestal assembly 248 is disposed in the interior volume 206 of the processing chamber 200 below the gas distribution (showerhead) assembly 230. The substrate support pedestal assembly 248 holds the substrate 402 during processing. The substrate support pedestal assembly 248 generally includes a plurality of lift pins (not shown) disposed therethrough that are configured to lift the 402 from the substrate support pedestal assembly 248 and facilitate exchange of the substrate 402 with a robot (not shown) in a conventional manner. An inner liner 218 may closely circumscribe the periphery of the substrate support pedestal assembly 248.

In one embodiment, the substrate support pedestal assembly 248 includes a mounting plate 262, a base 264 and an electrostatic chuck 266. The mounting plate 262 is coupled to the bottom 210 of the chamber body 202 includes passages for routing utilities, such as fluids, power lines and sensor leads, among other, to the base 264 and the electrostatic chuck 266. The electrostatic chuck 266 comprises at least one clamping electrode 280 for retaining a substrate 402 below showerhead assembly 230. The electrostatic chuck 266 is driven by a chucking power source 282 to develop an electrostatic force that holds the substrate 402 to the chuck surface, as is conventionally known. Alternatively, the substrate 402 may be retained to the substrate support pedestal assembly 248 by clamping, vacuum or gravity.

At least one of the base 264 or electrostatic chuck 266 may include at least one optional embedded heater 276, at least one optional embedded isolator 274 and a plurality of conduits 268, 270 to control the lateral temperature profile of the substrate support pedestal assembly 248. The conduits 268, 270 are fluidly coupled to a fluid source 272 that circulates a temperature regulating fluid therethrough. The heater 276 is regulated by a power source 278. The conduits 268, 270 and heater 276 are utilized to control the temperature of the base 264, thereby heating and/or cooling the electrostatic chuck 266. The temperature of the electrostatic chuck 266 and the base 264 may be monitored using a plurality of temperature sensors 290, 292. The electrostatic chuck 266 may further comprise a plurality of gas passages (not shown), such as grooves, that are formed in a substrate support pedestal supporting surface of the chuck 266 and fluidly coupled to a source of a heat transfer (or backside) gas, such as He. In operation, the backside gas is provided at controlled pressure into the gas passages to enhance the heat transfer between the electrostatic chuck 166 and the substrate 402.

In one embodiment, the substrate support pedestal assembly 248 is configured as a cathode and includes an electrode 280 that is coupled to a plurality of RF power bias sources 284, 286. The RF bias power sources 284, 286 are coupled between the electrode 280 disposed in the substrate support pedestal assembly 248 and another electrode, such as the showerhead assembly 230 or ceiling (lid 204) of the chamber body 202. The RF bias power excites and sustains a plasma discharge formed from the gases disposed in the processing region of the chamber body 202.

In the embodiment depicted in FIG. 2, the dual RF bias power sources 284, 286 are coupled to the electrode 280 disposed in the substrate support pedestal assembly 248 through a matching circuit 288. The signal generated by the RF bias power 284, 286 is delivered through matching circuit 288 to the substrate support pedestal assembly 248 through a single feed to ionize the gas mixture provided in the plasma processing chamber 200, thereby providing ion energy necessary for performing a deposition or other plasma enhanced process. The RF bias power sources 284, 286 are generally capable of producing an RF signal having a frequency of from about 50 kHz to about 200 MHz and a power between about 0 Watts and about 5000 Watts. An additional bias power source 289 may be coupled to the electrode 280 to control the characteristics of the plasma.

In one mode of operation, the substrate 402 is disposed on the substrate support pedestal assembly 248 in the plasma processing chamber 200. A process gas and/or gas mixture is introduced into the chamber body 202 through the showerhead assembly 230 from the gas panel 258. A vacuum pump system 228 maintains the pressure inside the chamber body 202 while removing deposition by-products.

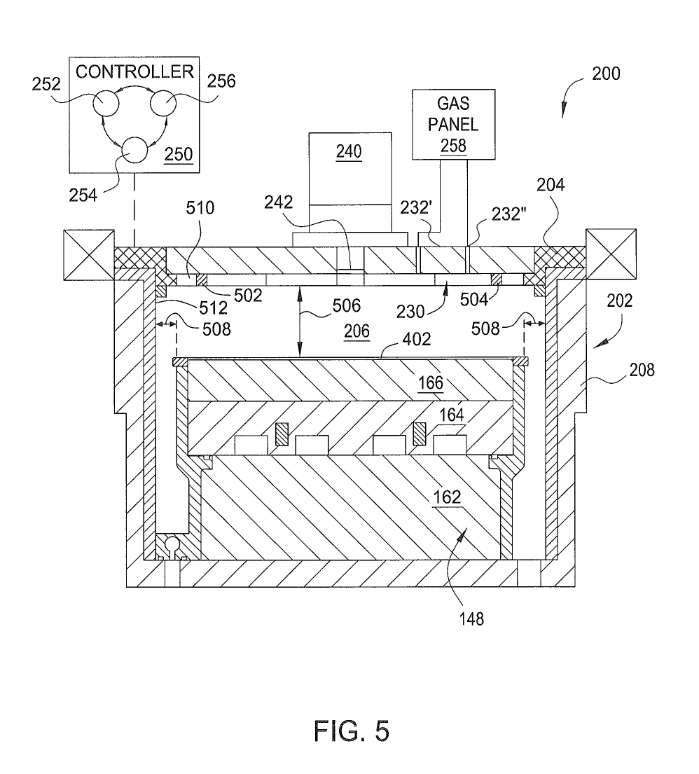

In one embodiment, a plurality of light sources 504, 502 may be positioned at a periphery region of the showerhead assembly 230. The light sources 504, 502 are adapted to enhance UV light, e.g., photons, emitted to the substrate 402 to facilitate chemical reaction during processing. The light sources 504, 502 may be arranged in annular groups. The light sources 504, 502 provides UV light, e.g., photons, near the edge of the substrate 402 thus enhancing distribution of the UV light, e.g., photons, to edges of the substrate 244. Details regarding the light sources 504 will be further described below with reference to FIG. 5.

A controller 250 is coupled to the processing chamber 200 to control operation of the processing chamber 200. The controller 250 includes a central processing unit (CPU) 252, a memory 254, and a support circuit 256 utilized to control the process sequence and regulate the gas flows from the gas panel 258. The CPU 252 may be any form of general purpose computer processor that may be used in an industrial setting. The software routines can be stored in the memory 254, such as random access memory, read only memory, floppy, or hard disk drive, or other form of digital storage. The support circuit 256 is conventionally coupled to the CPU 252 and may include cache, clock circuits, input/output systems, power supplies, and the like. Bi-directional communications between the controller 250 and the various components of the processing system 100 are handled through numerous signal cables.

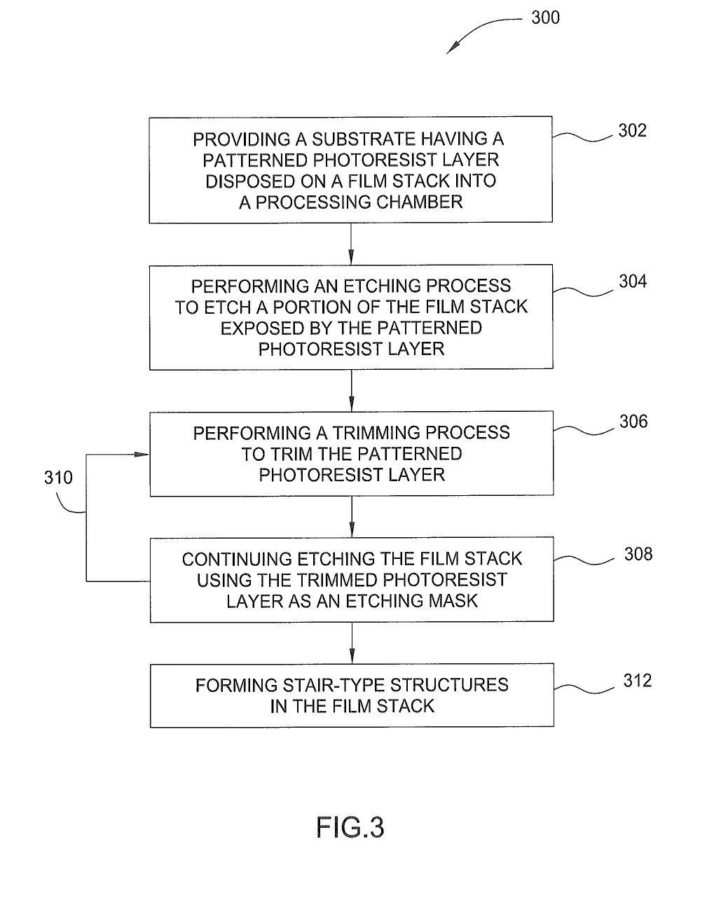

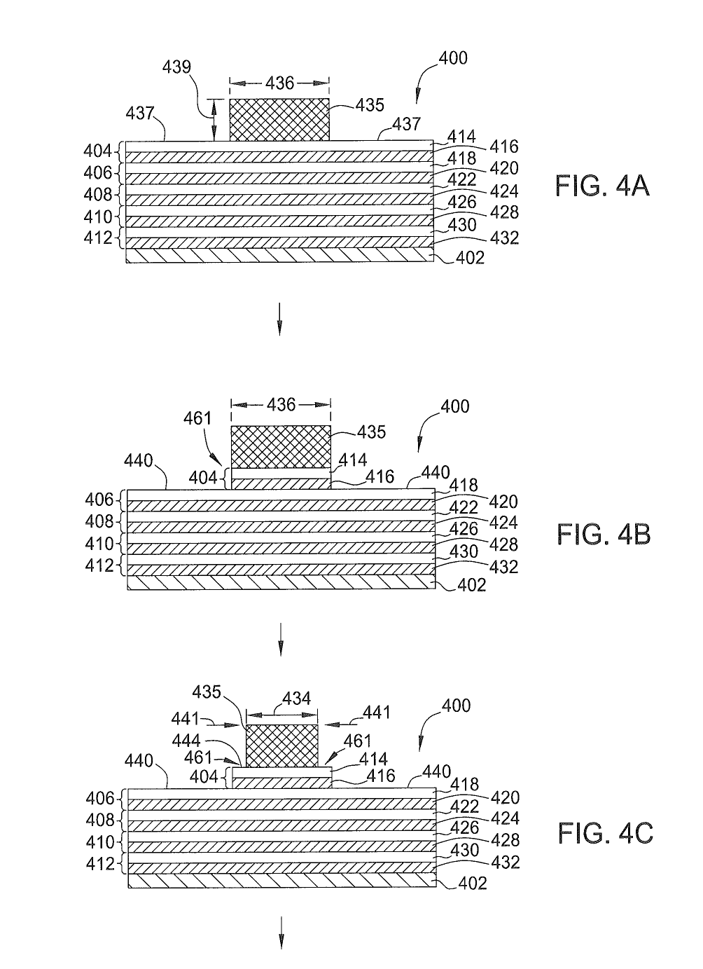

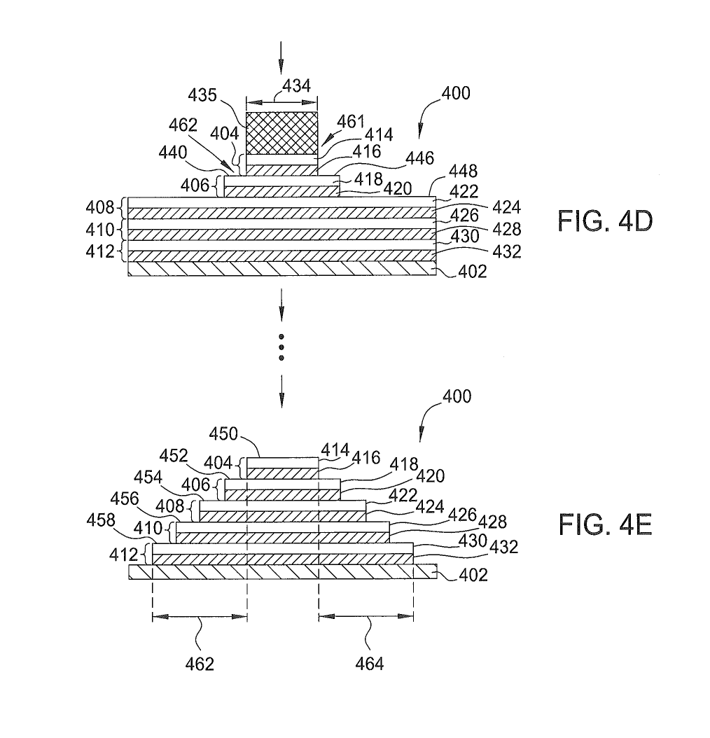

FIG. 3 is a flow diagram of one embodiment of a method 300 for forming stair-like structures in a film stack disposed on a substrate that may be performed in a processing chamber, such as the processing chamber 200 depicted in FIG. 2. FIGS. 4A-4E are schematic cross-sectional view illustrating a sequence for forming stair-like structures in a film stack disposed on a substrate according to the method 300. Although the method 300 is described below with reference to a substrate utilized to manufacture stair-like structures in a film stack for three dimensional semiconductor chips, the method 300 may also be used to advantage in other transistor device manufacture applications.

The method 300, which may be stored in computer readable form in the memory 254 of the controller 250 or a substrate 402 or other suitable location, begins at block 302 by transferring the substrate support pedestal assembly 248 disposed in a processing chamber, such as the processing chamber 200 depicted in FIG. 2. The substrate 402 may be an optically silicon based material or any suitable insulating materials or conductive materials as needed, having a film stack 400 disposed on the substrate 402 that may be utilized to form desired stair-like structures in the film stack 400.

As shown in the exemplary embodiment depicted in FIG. 4A, the substrate 402 may have a substantially planar surface, an uneven surface, or a substantially planar surface having a structure formed thereon. The film stack 400 is formed on the substrate 402. In one embodiment, the film stack 400 may be utilized to form a gate structure, a contact structure or an interconnection structure in the front end or back end processes. The method 300 may be formed on the film stack 400 to form the stair-like structures therein. In one embodiment, the substrate 402 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 402 may have various dimensions, such as 200 mm, 300 mm, 450 mm or other diameter wafers, as well as, rectangular or square panels. Unless otherwise noted, embodiments and examples described herein are conducted on substrates with a 200 mm diameter, a 300 mm diameter, a 450 mm diameter substrate. In the embodiment wherein a SOI structure is utilized for the substrate 402, the substrate 402 may include a buried dielectric layer disposed on a silicon crystalline substrate. In the embodiment depicted herein, the substrate 402 may be a crystalline silicon substrate.

In one embodiment, the film stack 400 disposed on the substrate 402 may have a number of vertically stacked layer stacks 404, 406, 408, 410, 412. The layer stacks 404, 406, 408, 410, 412 formed in the film stack 400 may be a part of a semiconductor chip, such as a three-dimensional (3D) memory chip. Although five layer stacks 404, 406, 408, 410, 412 are shown in FIG. 4A-4E, it is noted that any desired number of layer stacks may be utilized as needed.

In one embodiment, the layer stacks 404, 406, 408, 410, 412 may be utilized to form multiple gate structures for a three-dimensional (3D) memory chip. Each of the layer stacks 404, 406, 408, 410, 412 may include at least two layers, respectively shown as a conductive layer 414, 418, 422, 426, 430 disposed on a dielectric layer 416, 420, 424, 428, 432, in FIG. 4A.

Examples of the materials suitable for use as conductive layer 414, 418, 422, 426, 430 may include polysilicon, doped silicon, such as n-type or p-type doped silicon, other suitable silicon containing material, tungsten (W), tungsten silicide (WSi), tungsten polysilicon (W/poly), tungsten alloy, tantalum (Ta), titanium (Ti), copper (Cu), ruthenium (Ru), nickel (Ni), cobalt (Co), chromium (Cr), iron (Fe), manganese (Mn), aluminum (Al), hafnium (Hf), vanadium (V), molybdenum (Mo), palladium (Pd), gold (Au), silver (Au), platinum (Pt), alloys thereof, nitride compound thereof, such as titanium nitride (TiN) and tantalum nitride (TaN), and combinations thereof, among others.

Examples of materials suitable for use as the dielectric layers 416, 420, 424, 428, 432 include silicon oxide, silicon nitride, silicon oxynitride, silicon carbide, nitride, titanium nitride, composite of oxide and nitride, at least one or more oxide layers sandwiching a nitride layer, and combinations thereof, among others. In some embodiments, the dielectric layer 416, 420, 424, 428, 432 may be a high-k material having a dielectric constant greater than 4. Suitable examples of the high-k materials include hafnium dioxide (HfO₂), zirconium dioxide (ZrO₂), hafnium silicon oxide (HfSiO₂), hafnium aluminum oxide (HfAIO), zirconium silicon oxide (ZrSiO2), tantalum dioxide (TaO₂), aluminum oxide, aluminum doped hafnium dioxide, bismuth strontium titanium (BST), and platinum zirconium titanium (PZT), among others.

In one particular embodiment, at least one of the layer stacks 404, 406, 408, 410, 412 include the conductive layer 414, 418, 422, 426, 432 of a polysilicon or doped polysilicon disposed on the dielectric layer 416, 420, 424, 428, 432 of silicon oxide.

In one embodiment, the thickness of conductive layer 414, 418, 422, 426, 432 may be controlled at between about 50 Å and about 1000 Å, such as about 500 Å, and the thickness of the each dielectric layer 416, 420, 424, 428, 432 may be controlled at between about 50 Å and about 1000 Å, such as about 500 Å. Each of the layer stacks 404, 406, 408, 410, 412 may have a total thickness between about 100 Å and about 2000 Å.

A patterned photoresist layer 435, a lithographically patterned mask, is then formed over the film stack 400 exposing portions 437 of the first stack layer 404 formed in the film stack 400 for etching. In one embodiment, the photoresist layer 435 may is a positive tone photoresist, a negative tone photoresist, a UV lithography photoresist, an i-line photoresist, an e-beam resist (for example, a chemically amplified resist (CAR)) or other suitable photoresist. In one embodiment, the photoresist layer 435 may include organic polymer materials, such as fluoropolymers, silicon-containing polymers, hydroxy styrene, or acrylic acid monomers to provide acid groups when the photoresist layer 435 is exposed to radiation. The choice of the material for the photoresist layer 435 depends on the particular microelectronic device processing application being performed. In particular, the choice of the material for the photoresist layer 435 depends on the properties of the photoresist layer 435 at a given wavelength of radiation. In alternate embodiments, the photoresist layer 435 is optimized to a wavelength of radiation, e.g., 365 nm, 248 nm, 193 nm, 157 nm, and 13 nm. In one embodiment, the photoresist layer 435 may be deposited to a thickness 439 between about 2000 nm and about 8000 nm and a first width 436 (e.g., an initial width) between about 2000 nm and about 100,000 nm.

At block 304, an etching gas mixture is supplied into the processing chamber 200 to etch the portions 437 of the first layer stack 404 in the film stack 400 exposed by the patterned photoresist layer 435, as shown in FIG. 4B. The patterned photoresist layer 435 servers as an etching mask during the etching process of the first layer stack 404. The first conductive layer 414 and the first dielectric layer 416 included in the first layer stack 404 may be continuously etched using one process step, such as a single etchant chemistry, or separately etched by multiple steps in one or different etching processes as needed. The patterns from the photoresist layer 435 are then transferred into the first layer stack 404, forming a first stair-like structure 461 through the etching process. The etching process may be continuously performed until a surface 440 of the second layer stack 406 is exposed with the first stair-like structure 461 and the patterned photoresist layer 435 disposed thereon.

In one embodiment, the etching gas mixture selected to etch the first conductive layer 414 and the first dielectric layer 416 has different chemistries. In one example, the etching gas mixture utilized to etch the first conductive layer 414 includes HBr, Cl₂, O₂, or combinations thereof, optionally may include an inert gas, such as Ar or He. The etching gas mixture utilized to etch the first dielectric layer 416 includes CF₄, CHF₃, CH₂F₂, O₂, or combinations thereof, and optionally may include an inert gas, such as Ar or He. In the embodiment wherein the first dielectric layer 416 is a silicon oxide layer, an etching gas mixture including C₄F₆, C₄F₈, CF₄, or combinations thereof may be utilized. In the embodiment wherein the first dielectric layer 416 is a silicon nitride layer, an etching gas mixture including CH₃F, CH₂F₂, CHF₃, or combinations thereof may be utilized. During etching, the process pressure may be maintained between about 5 mTorr and about 30 mTorr. A RF source power may be controlled at between about 500 Watts and about 5000 Watts. A RF bias power may be controlled at between about 50 Watts and about 800 Watts.

At block 306, after the first layer stack 404 is etched by the first etching gas mixture supplied at block 304, a trimming process is performed. The trimming process is performed to reduce the first width 436 of the photoresist layer 435 to a second width 434, as shown in FIG. 4C. The trimming process reduces the first width 436 of the photoresist layer 435 to the second width 434 in a lateral direction 441 to expose a portion 444 of the first stair-like structure 461 etched in first layer stack 404. The trimming process at block 306 and the etching process at block 304 may be in-situ performed in a single processing chamber using different chemistries.

In one embodiment, the trimming gas mixture is supplied to the etch chamber to trim the photoresist layer 435 to the second width 434 with the predetermined critical dimension. During trimming, the photoresist layer 435 is trimmed in the lateral direction 441 before the trimmed photoresist layer 435 is utilized as the etch mask for the subsequent etching processes. As the dimension of the photoresist layer 435 may be further reduced during the subsequent etching process, which will be further described below, the trimming process performed at block 306 may be configured to trim the photoresist layer 435 to the predetermined second width 434, but not to the final and last dimension, so as to form a second stair-like structure in the second layer stack 406 at this stage.

In one embodiment, the trimming process trims the first width 436, e.g., critical dimension, of the photoresist layer 435 to about 10,000 nm to the second with 434 about 9000 nm or less. The trimming gas mixture is selected to have a high selectivity for the photoresist layer 435 over the layer stacks 404, 406, thereby predominantly trimming the photoresist layer 435 rather than etching the exposed first stair-like structure 461 and the exposed surface 440 of the second layer stack 406. In one embodiment, the trimming gas mixture includes, but not limited to, a oxygen containing gas accompanying by an optional nitrogen containing gas and/or an inert gas. Examples of the oxygen containing gas includes O₂, NO, N₂O, CO₂, CO and the like. Examples of the nitrogen containing gas includes N₂, NO, N₂O, NH₃ and the like. Alternatively, inert gas, such as Ar or He, may also be incorporated with the first trimming gas into the etch chamber.

Several process parameters are regulated while the trimming gas mixture at block 306 supplied into the processing chamber. In one embodiment, the chamber pressure in the presence of the trimming gas mixture is regulated to a relatively high process pressure, such as greater than 25 mTorr, for example between about 30 mTorr to about 200 mTorr, for example, such as between about 33 mTorr and about 80 mTorr. It is believed that higher process pressure may assist improving trimming gas to reach to the substrate edge, thereby improving trimming uniformity across the substrate surface. The trimming gas mixture may include an oxygen gas flowed into the chamber at a rate between about 10 sccm to about 1000 sccm. The nitrogen containing gas may be supplied at a rate between about 20 sccm and about 200 sccm. It is believed that a relatively lower oxygen containing gas flow rate, such as less than 600 sccm, for example less than 300 sccm, may enhance the trimming gas flow to the edge of the substrate, thereby improving trimming rate uniformity. In one example, the oxygen containing gas used in the trimming gas mixture is O₂ and the nitrogen containing gas used in the trimming gas is N₂. In an exemplary embodiment, the O₂ gas and N₂ gas is supplied in the trimming gas mixture at a O₂:N₂ ratio greater than about 5, such as between about 4:1 and about 10:1. A substrate temperature may be maintained between about 10 degrees Celsius to about 500 degrees Celsius, such as about 88 degrees Celsius.

RF source power may be applied to maintain a plasma formed from the trimming process gas. For example, a source power of about 500 Watts to about 5000 Watts, such as about 2500 Watts, may be applied to an inductively coupled antenna source to maintain a plasma inside the etch chamber. In one embodiment, a pulsed mode RF source power may be utilized during the trimming process. It is believed that the RF source power utilized in pulse mode, along with a frequency greater than 500 Hz, such as greater than 1 kHz, may assist generate lower amount of reactive species and UV light during processing. However, the amount of UV light as generated decreases faster than the amount of reactive species, at a duty cycle of 20 percent. For example, an intensity of UV light decreases by 80 percent while the density of reactive species decreases by 50 percent. Therefore, as relative impact of the UV light, e.g., photons, decreases, asymmetry of the trimming rate decreases. In one embodiment, the RF source power may be pulsed into the processing chamber 200 at a duty cycle between about 20 percent and about 50 percent.

Furthermore, during the trimming process at block 306, a light energy from the light sources 502, 504 may be provided to the edge of the substrate 402, thereby enhancing the trimming rate of the photoresist layer at the edge of the substrate 402. It is believed that the light energy, e.g., photons, from the light sources 502, 504 may enhance generation of the UV light, e.g., photons, at the edge of the substrate, thereby enhancing the trimming rate at the substrate edge. In one embodiment, the light source 502, 504 may emit a light energy at a wavelength between about 110 nm and about 600 nm. The light energy may include a UV light.

At block 308, a second etching process is performed to etch the second stack layer 406 to form a second stair-like structure 462 in the second stack layer 408 using the first stair like structure 461 as an etching mask while further etching the first stair-like structure 461 through its exposed surface 444 (as shown in FIG. 4C) to reduce its dimension from the first width 436 to the second width 434 defined by the trimmed photoresist layer 435, as shown in FIG. 4D. The second etching process is generally an anisotropic etch process (e.g., anisotropic plasma etch process) that mainly vertically etches the first stair-like structure 461 exposed by the trimmed photoresist layer 435 and the second stack layer 408 exposed by the first stair-like structure 461. In one embodiment, the second stack layer 408 is etched until an underlying upper surface 448 of the third stack layer 408 is exposed, forming the second stair-like structure 462 in the second stack layer 408. The first stair-like structure 461 exposed by the exposed surface 444 is etched until the underlying upper surface 440 of the second stair-like structure 462 is exposed. Accordingly, after the second etching process, at least two stair-like structures 461, 462 are formed respectively in the first and the second stack layer 404, 406.

Similar to the first etching process performed at block 304, the etching process at block 308 is performed by supplying a second etching gas mixture to the processing chamber 200. In one example, the second etching gas mixture may be the same or similar to the first etching gas mixture supplied at block 304 when the layers in the first and the second stack layers 404, 406 are configured to have the same or similar materials. In another embodiment, the second etching gas mixture may have different chemistries to the first etching gas mixture when the layers in the first and the second stack layers 404, 406 have different materials. In an exemplary embodiment depicted herein, the first etching gas mixture at block 304 has the same chemistries as that of in the second etching gas mixture at block 308.

As discussed above, the trimmed photoresist layer 435 and the first stair-like structure 461 may serve as etching masks during the etching process of forming the second stair-like structure 462. The second conductive layer 418 and the second dielectric layer 420 included in the second layer stack 406 may be continuously etched using one process step, such as a single etchant chemistry, or separately etched by multiple steps in one or different etching processes as needed. The patterns from the trimmed photoresist layer 435 are then translated into the second layer stack 406, as well as the first layer stack 404, forming the second stair-like structure 462 and the reduced dimension first stair-like structure 461 through the etching process. The etching process may be continuously performed until the upper surface 448 of the third second layer stack 408 is exposed.

Similarly, in one embodiment, the second etching gas mixture selected to etch the second conductive layer 418 and the second dielectric layer 420 has different chemistries. In one example, the second etching gas mixture utilized to etch the second conductive layer 418 includes HBr, Cl₂, O₂, or optionally an inert gas, such as Ar or He, and combinations thereof. The second etching gas mixture utilized to etch the second dielectric layer 420 includes CF₄, CHF₃, CH₂F₂, O₂, or optionally an inert gas, such as Ar or He, and combinations thereof. In the embodiment wherein the second dielectric layer 420 is a silicon oxide layer, an etching gas mixture including C₄F₆, C₄F₈, CF₄, or combinations thereof may be utilized. In the embodiment wherein the second dielectric layer 420 is a silicon nitride layer, the second etching gas mixture including CH₃F, CH₂F₂, CHF₃, or combinations thereof may be utilized.

It is noted that the trimming process at block 306 and the etching process at block 308 may be repeatedly performed, as indicated by the loop 310, to etch the film stack 400 until desired numbers of the stair-like structures are formed in each remaining individual layer stacks 408, 410, 412.

At block 112, after numbers of the etching and trimming process, five stair like structures are individually formed in each layer stack 404, 406, 408, 410, 412 disposed on the substrate 402, as shown in the exemplary embodiment depicted in FIG. 4E, exposing portions 450, 452, 454, 456, 458 of the layer stack 404, 406, 408, 410, 412 to form the stair like structures. After the stair like structures are formed in the film stack 400, the remaining photoresist layer 435 may be then removed from the substrate 402. In one embodiment, the remaining photoresist layer 435 is removed by ashing. The removal process may be performed in-situ the processing chamber 200 in which the etching and trimming process performed at block 304-308 was performed. In the embodiment wherein the photoresist layer 435 is completely consumed during the etching and trimming process, the ashing or photoresist layer removal process may be eliminated.

By using this trimming process and etching process performed by method 300, symmetric stair like structures with substantially symmetric widths 462, 464 at two sides of the stair like structures may be obtained.

FIG. 5 depicts a partially enlarged view of the processing chamber 200 depicted in FIG. 2 in accordance with another embodiment of the present invention. As discussed above, the external light sources 502, 504 are disposed in a periphery region 510 of the showerhead assembly 230, opposite to the edge of the substrate 402. It is found the plasma as generated during process often include light emission and reactive species. In other words, high energy UV light is often found in the plasma. When UV light reaches to the photoresist layer on the substrate, it enhances the chemical reaction between the reactive species from the plasma and the photoresist layer. Insufficient UV light traveled close to sidewalls 512 of the processing chamber 200 often result in insufficient or asymmetric distribution of UV light around an edge of the substrate 402, thereby creating unbalanced etching/trimming rates across the substrate surface. By adding additional light sources 502, 504 at periphery region 510 of the showerhead assembly 230, UV light, e.g., photons, generated from the light sources 502, 504 may enhance chemical reaction at around the edge of the substrate 402 where the light sources 502, 504 are emitted to, thereby enhancing etching/trimming rate at the edge of the substrate 402. It is believed that the light sources 504, 502 enhance UV light, e.g., photons, to the substrate 402, facilitating chemical reaction extending to edges of the substrate 402.

In one embodiment, the light sources 504, 502 may be arranged in annular groups. The numbers of the light sources 504, 502 implanted into the showerhead assembly 230 may be in any number as needed. In one example, two light sources are placed in the lid 104. The light sources 504, 502 may provide a UV light source at a wavelength range between about 110 nm and about 600 nm.

Additionally, a gap 508 between the substrate support pedestal assembly 248 and the chamber sidewall 512 as well as a distance 506 defined between the substrate 402 and the showerhead assembly 230 may also assist alerting the reactive radical distribution/profile formed across the substrate surface. It is believed a relatively larger gap 508 between the substrate support pedestal assembly 248, that supports the substrate 402 during processing, and the chamber liner of sidewalls 512 may promote the plasma to extend beyond the substrate edges. The extended plasma act as an additional source of UV light, enhancing chemical reaction occurred to the substrate surface. In one embodiment, the gap 508 defined between the chamber sidewall 512 and the substrate support pedestal assembly 248 is greater than 5 inch, such as between about 6 inch and about 10 inch. As the gap 508 defined between the chamber sidewall 512 and the substrate support pedestal assembly 248 is increased, the size of the processing chamber 200, as well as the interior volume 206 defined therein, is correspondingly greater. In one embodiment, the interior volume 206 of the processing chamber 200 configured for a 300 mm substrate with diameter may be about greater than 15 percent to 50 percent from internal volume of a conventional processing chamber.

Additionally, by shortening the distance 506 between the showerhead assembly 230 and the substrate 402, it is believed a relatively more compact and high density reactive radical profile may be maintained in the interior volume 206 of the processing chamber 200 during processing. The intense reactive radical distribution close to the substrate surface efficiently improves trimming/etching rate. In one embodiment, the distance 506 between the chamber lid 204 and the substrate support assembly 148 may be maintained between about 3000 mils and about 6000 mils.

Thus, methods and apparatus for forming stair-like structures for manufacturing three dimensional (3D) stacking of semiconductor chips are provided. The methods and the apparatus may advantageously provide an enhanced trimming and etching rate at edges of the substrate during processing, thereby improving uniformity of the resultant stair-like structures formed in a film stack disposed on a substrate in applications for three dimensional (3D) stacking of semiconductor chips.

While the foregoing is directed to embodiments of the present invention, other and further embodiments of the invention may be devised without departing from the basic scope thereof, and the scope thereof is determined by the claims that follow.

1. A method of forming stair-like structures on a substrate, comprising:
performing a trimming process on a substrate to trim a patterned photoresist layer disposed on a film stack from a first width to a second width in a processing chamber, wherein the patterned photoresist layer exposes a portion of the film stack uncovered by the patterned photoresist layer during the trimming process, wherein the trimming process further comprises:
supplying a trimming gas mixture including at least an oxygen containing gas; and
providing a light energy in the trimming gas mixture to an edge of the substrate during the trimming process.

2. The method of claim 1, wherein supplying the trimming gas mixture further comprises:
supplying a nitrogen containing gas in the trimming gas mixture, wherein the oxygen containing gas and the nitrogen containing gas at a ratio greater than 5.

3. The method of claim 1, wherein supplying the trimming gas mixture further comprises:
supplying the oxygen containing gas mixture less than 300 sccm.

4. The method of claim 1, wherein supplying the trimming gas mixture further comprises:
maintaining a process pressure greater than about 25 mTorr.

5. The method of claim 1, wherein supplying the trimming gas mixture further comprises:
applying a source RF power to form a plasma in the trimming gas mixture in a pulsed mode.

6. The method of claim 6, wherein the source RF power has a frequency greater than 500 Hz.

7. The method of claim 1, wherein supplying the trimming gas mixture further comprises:
maintaining the substrate at a distance from a showerhead disposed in the processing chamber between about 3000 mils and about 6000 mils.

8. The method of claim 1, wherein supplying the trimming gas mixture further comprises:
maintaining the substrate disposed on a substrate support pedestal at a distance from a chamber wall between about 6 inch and about 10 inch.

9. The method of claim 1, wherein providing a light energy to the edge of the substrate during the trimming process further comprises:
emitting the light energy having a wavelength between about 110 nm and about 600 nm to the edge of the substrate.

10. The method of claim 9, wherein providing the light energy to the edge of the substrate during the trimming process further comprises:
emitting the light energy from a light source disposed at a periphery region of a showerhead assembly disposed in the processing chamber located opposite the edge of the substrate.

11. The method of claim 1, wherein the light energy is a UV light.

12. The method of claim 1, wherein the film stack includes at least one stack layer having a conductive layer disposed on a dielectric layer.

13. The method of claim 1, further comprising:
etching the film stack using the trimmed photoresist layer as an etching mask to form a stair-like structure in the film stack.

14. The method of claim 13, further comprising:
repeatedly performing the trimming process and the etching process until desired numbers of the stair-like structures are formed in the film stack.

15. An apparatus for manufacturing stair-like structures in a film stack for three dimensional stacking of semiconductor chips comprising:
a chamber body having a chamber sidewall and a chamber lid disposed on the chamber sidewall defining an interior volume of an etching processing chamber;
a substrate support pedestal disposed in the interior volume of the etching processing chamber;
a showerhead assembly disposed opposite to the substrate support pedestal; and
a plurality of light source disposed in a periphery region of the chamber lid facing an edge of the substrate support assembly.

16. The apparatus of claim 15, wherein the plurality of light source is arranged in annular groups.

17. The apparatus of claim 15, wherein the light source is operable to provide a light energy at a wavelength between about 110 nm and about 600 nm.

18. The apparatus of claim 15, wherein the light source is operable to provide a UV light.

19. The apparatus of claim 15, wherein the substrate support pedestal and the showerhead assembly has a distance between about 3000 mils and about 6000 mils.

20. The apparatus of claim 15, wherein substrate support pedestal and the chamber sidewall has a gap greater than 6 inch.
